(19) United States
(12) Patent Application Publication
(10) Pub. No.: US 2002/0150183 A1
(43) Pub. Date: Oct. 17, 2002

(54) Apparatus comprising a receiving device for receiving data organized in frames and method of reconstructing lacking information

(76) Inventor: Gilles Miet, Le Mans (FR)

Correspondence Address: Corporate Patent Counsel, U.S. Philips Corporation, 580 White Plains Road, Tarrytown, NY, 10591, US

(21) Appl. No.: 10/023,397

(22) Filed: Dec. 13, 2001

(30) Foreign Application Priority Data
Dec. 19, 2000 (FR) 0016592

(51) Int. Cl. G10L 11/00; G10L 21/00; G10L 19/12; G10L 21/02; H03D 1/00; H04L 27/06

(52) U.S. Cl. 375/343; 704/202; 704/221; 704/226

(57) ABSTRACT

This apparatus (1) is intended to be connected to a cellular telephone network which transmits data in frames (HTR). This apparatus comprises a data reconstructing device (30) triggered by a signal (BFR) which indicates received bad data of a frame before this frame is reconstructed. The data are reconstructed by means of established waveforms of correctly received preceding data. The frame is reconstructed by copying the estimated waveform (w^{est}i) as many times as necessary.

The invention relates to an apparatus comprising a receiving device for receiving data, the apparatus including a bad data detection device for producing a signal indicating bad data and a data reconstruction device triggered by said indication signal for reconstructing the bad data.

The invention also relates to a method of reconstructing data considered bad.

Such an apparatus is known from U.S. Pat. No. 5,907,822. In this document it is proposed to reconstruct a speech signal frame when this is estimated to be erroneous or unfit for generating a suitable signal. This reconstruction is effected on the basis of decoding parameters of the frame data which are thus linked to the type of the decoding system.

The present invention proposes an apparatus of the type mentioned in the opening paragraph which reconstructs the frames considered defective in an independent manner of the decoder.

Therefore, such an apparatus is characterized in that the reconstruction device comprises means for reconstructing waveforms based on previously received data and for reconstructing lacking data by extrapolation of said waveforms.

The idea of the invention thus consists of utilizing waveforms which describe the sound message well. This use of waveform adapted to both speech and music is particularly appreciated by the user for whom the thus reconstructed data may pass unnoticed.

These and other aspects of the invention are apparent from and will be elucidated, by way of non-limitative example, with reference to the embodiment(s) described hereinafter.

In the drawings:

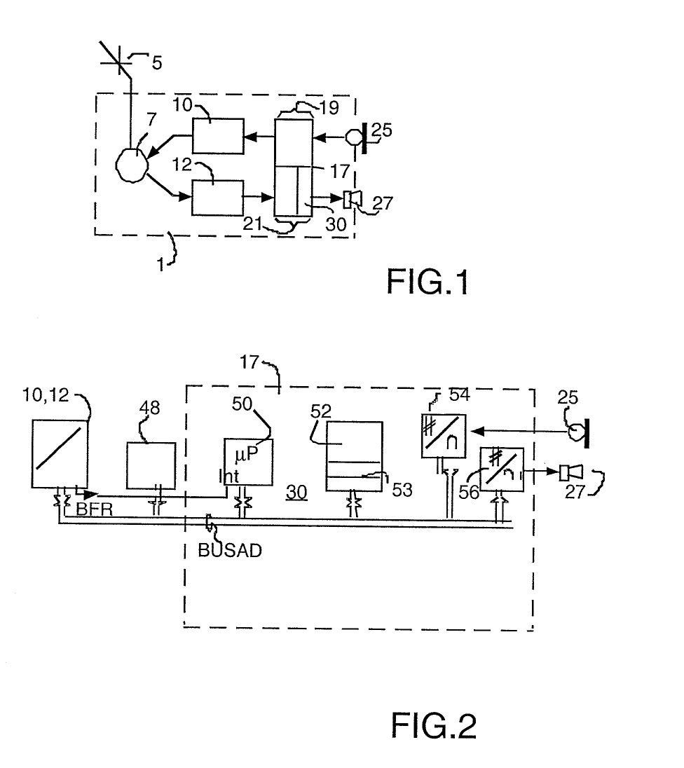

FIG. 1 shows an apparatus in accordance with the invention,

FIG. 2 shows a diagram of the frame reconstruction device,

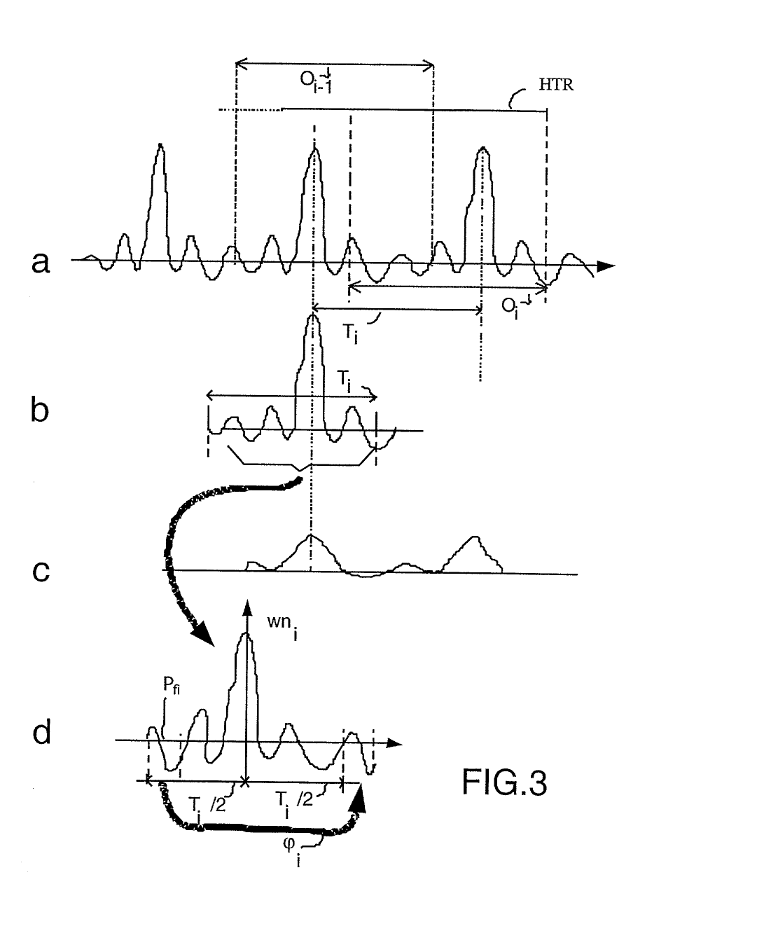

FIG. 3 shows a first timing diagram showing the processing of correctly received waveforms,

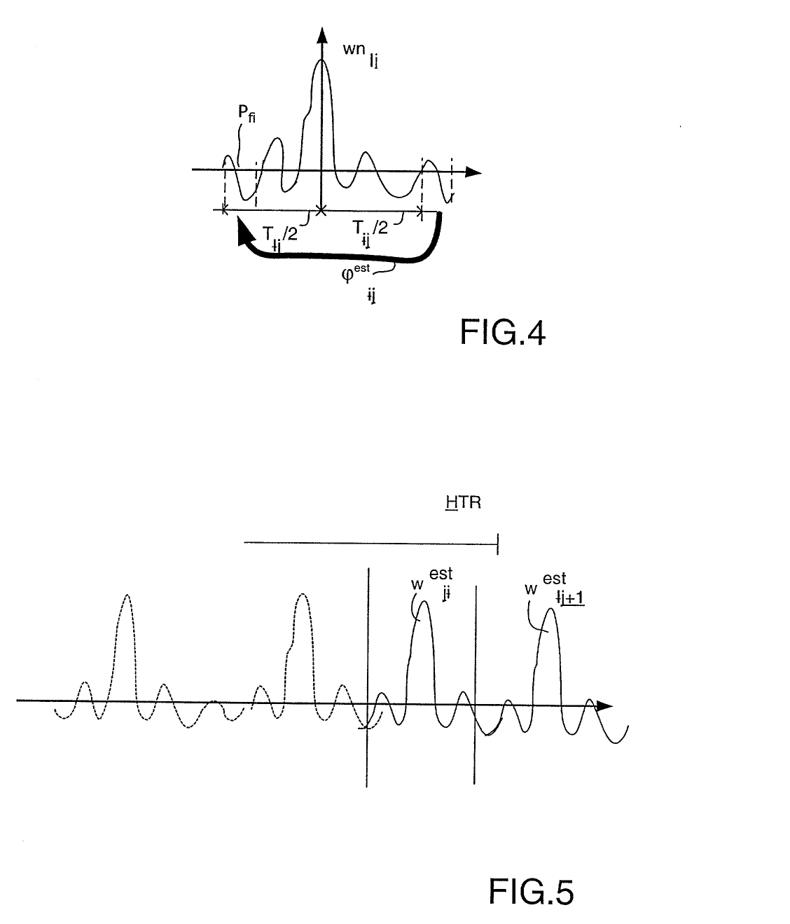

FIG. 4 shows a second timing diagram showing the preparation of the waveform that can be used for the reconstruction of the frame,

FIG. 5 shows a third timing diagram showing the reconstruction of the frame considered bad.

FIG. 1 shows an apparatus 1 in accordance with the invention. It is a mobile cellular radiotelephone which satisfies the GSM or UMTS standards, for example. It is formed by an antenna 5 for transmitting and receiving radio signals. This antenna 5 is coupled via a duplexer 7 to a transmitting part 10 and a receiving part 12. The acoustic signals which are present in the form of frames are processed in an acoustic signal processing assembly 17 which is in the form of a coding system 19 and a decoding system 21. These systems are connected to a microphone 25 and a loudspeaker 27, respectively. The assembly 17 may incorporate a frame reconstruction system 30.

FIG. 2 shows a diagram of the frame reconstruction device 17 which uses components for other functions. This device thus processes inter alia the speech signals produced by the decoder 48. This device 17 is built around a processor 50 to which a memory assembly 52 is added in customary manner, which memory assembly 52 comprises, on the one hand, the program which implements the measures according to the invention and, on the other hand, fixed and variable data which this program needs. One part 53 of this memory is intended to contain speech samples coming from the decoder 17 and other useful data for the frame reconstruction. The thus processed data are transported over a common variable data line BUSAD. An analog-to-digital converter 54 converts the signals produced by the microphone 25 and a digital-to-analog converter 56 supplies acoustic data to the loudspeaker 27. All these components are connected via the line BUSAD to the parts 10 and 12. It will be noted that the receiving part produces a signal BFR which indicates, when active, that a received signal frame is bad. This signal is applied to an interrupt input Int of the processor 50 to trigger a processing proposed by the invention. Notably the GSM standards require to measure the quality of received frames and the signal BFR is thus produced in all the apparatus that satisfy this standard.

According to the invention a frame called bad frame will be reconstructed based on the analysis of the most recently received samples and which are considered to have good quality. These most recently received samples are analyzed as waveforms.

The principles of the invention are based on the following considerations.

FIG. 3 shows a diagram in which the invention is explained.

The line <<a>> of this Figure shows the shape of the speech signal stored in the form of digital samples at the memory locations 53. This signal is formed by the decoder 48.

When a bad frame arrives at the input of the decoder, the signal stored in the hyperframe (HTR) formed by various good frames is extracted (line <<a>>).

Observations are then made periodically during time windows. In the Figure are shown the windows Oᵢ and Oᵢ₋₁. These windows appear periodically but they often have a different timing of the frames (perhaps from 3 times slower to 5 times faster than the decoder 48). But the end of the last window Oᵢ of good data is arranged so that it coincides with the end of the hyperframe HTR shown. During these periods Oᵢ the speech signal is tapped and accordingly a signal wᵢ is formed whose shape is shown in line <<b>>. A correlation of this signal is effected until a correlation peak is obtained which is shown in line <<c>>. This maximum correlation with passed samples occurs after a time shift Tᵢ. This time Tᵢ gives a value of the period of the speech signal at the moment under consideration. This may be written as:

$${N}_{i} = a r g {max}_{N} \{ {\sum }_{k = 0}^{R - 1} {w}_{i} ( k ) * {w}_{i} ( k - N ) \} with N < {N}_{corr} \qquad ( 1 )$$

N_{corr} is the in-depth limit of the correlation. R being the number of samples contained in the window Oᵢ. Subsequently, a waveform is defined based on this period. The signal is extracted over a period within the observation window Oᵢ as indicated by curve <<b>>. Thereafter it is made periodic:

∀m ∈Z, ∀k ∈[0 . . . K−1], \tilde{w}ᵢ(k+m.K)=wᵢ(k+ε), with K=Tᵢ. Fe (2)

However, attention should be paid to the fact that the ends of the signal have a low amplitude so as not to create discontinuity between its ends (slight additional shift ε of several samples). This signal is then standardized for the time being (formula (2)) during a reference period. Within the framework of the example described a maximum period Tₘₐₓ is taken, that is to say, the lengths of the awaited waveforms are supposed not to exceed this value.

$$\tilde{w} {n}_{i} ( k ) = {\tilde{w}}_{i} ( k \cdot \frac{{T}_{i}}{{T}_{max}} ) \qquad ( 3 )$$

Thereafter the signal is shifted so as to be closest to the preceding waveform wnᵢ₋₁ as indicated in formula (4)

$${ϕ}_{i} = \frac{2 π}{F e \cdot {T}_{max}} \cdot a r g {max}_{N} \{ {\sum }_{k = 0}^{K - 1} w {n}_{i - 1} ( k ) * \tilde{w} {n}_{i} ( k + N ) \} \qquad ( 4 )$$

Take, for example, line <<d>>, where the part of samples P_{φi} situated after the time Tᵢ/2 is put before the samples of the window Oᵢ so as to stick best to the preceding waveform which had its maximum in the center of the standardized window (line <<c>>).

This waveform wnᵢ may thus be written as:

$$w {n}_{i} ( k ) = \tilde{w} {n}_{i} ( k + \frac{{ϕ}_{i}}{2 π} \cdot {T}_{max} \cdot F e ) \qquad ( 5 )$$

Fe being the frequency of the samples that form the various signals, Φᵢ defining the phase shift of said part P_{Φi}.

The waveform is then stored just like a certain number of them in said part of the memory 53. Similarly holds for the different periods Tᵢ and also for the signals Φᵢ. According to a characteristic of the invention the degree of periodicity cᵢ is evaluated for the waveform wnᵢ. This is effected by means of a correlation with the preceding waveform wnᵢ₋₁ already estimated:

$${c}_{i} = \frac{{\sum }_{k = 1}^{K} w {n}_{i} ( k ) \cdot w {n}_{i - 1} ( k )}{\sqrt{{\sum }_{k = 1}^{K} w {{n}_{i} ( k )}^{2} \cdot {\sum }_{k = 1}^{K} w {{n}_{i - 1} ( k )}^{2}}} \qquad ( 6 )$$

The reconstruction of the waveforms lost on reception of bad frames takes place as follows:

Letj=i+1 . . . i+Q (the bad data corresponding to the duration of the observations Oᵢ₊₁ . . . O_{Q}). Three evolution functions f( ), g( ) and h( ) are considered which permit to form the estimated period T^{est}j , the degree of estimated periodicity c^{est}j and the estimated waveform wn^{est}j, respectively, according to the following formulas

T^{est}ⱼ=ƒ(T_{j-L}, . . . , Tⱼ₋₁) (7)

c^{est}ⱼ=g(c_{j-L}, . . . , cⱼ₋₁) (8)

wn^{est}ⱼ=h(wn_{j-L}, . . . , wnⱼ₋₁) (9)

To have the reconstructed waveform w^{est}j (see FIG. 4), a reverse operation to the temporal standardization is made:

$${w}_{j}^{est} ( k ) = w {n}_{j}^{est} ( ( k - \frac{{ϕ}_{j}}{2 π} \cdot {T}_{j}^{est} \cdot {F}_{e} ) \cdot \frac{{T}_{max}}{{T}_{j}^{est}} ) \qquad ( 10 )$$

The phase shift is restored thanks to Φ^{est}I, so that the connection with the waveforms contained in the last correctly received frame (or previously reconstructed) can be made in a continuous manner. It is this last thus estimated waveform that will be used for reconstructing the frame considered bad (active signal BFR). FIG. 5 shows how the bad frame is reconstructed. These waveforms w^{est}j are reconstructed as many times as necessary for replacing the defective frames.

According to a characteristic feature of the invention noise will be added as a function of the correlation factor mentioned previously.

The various functions f( ), g( ) and h( ) which have been mentioned may be simple extrapolation functions. Thus, for example, for the period Tⱼ:

$${T}_{j} = \frac{{T}_{j - 1} \cdot ( j - ( j - 2 ) ) + {T}_{j - 2} \cdot ( ( j - 1 ) - j )}{( j - 1 ) - ( j - 2 )} = 2 \cdot {T}_{j - 1} - {T}_{j - 2} \qquad ( 11 )$$

1. An apparatus comprising a receiving device for receiving data, the apparatus including a bad data detection device for producing a signal indicating bad data and a data reconstruction device triggered by said indication signal for reconstructing the bad data, characterized in that the reconstruction device comprises means for reconstructing waveforms based on previously received data and for reconstructing lacking data by extrapolation of said waveforms.

2. An apparatus as claimed in claim 1, whose receiving device receives data in the form of frames for which the bad data indication signal is active for a bad frame, characterized in that the reconstruction device produces reconstructed data for replacing the whole frame that has been declared bad.

3. An apparatus as claimed in one of the claims 1 to 2, characterized in that said waveforms are standardized during a time period called reference period before extrapolation and in that the reconstructed waveform is destandardized as a function of an extrapolated duration.

4. An apparatus as claimed in one of the claims 1 to 3, characterized in that the reconstruction device comprises an adder of noise whose magnitude is based on the degree of correlation between the waveforms already passed.

5. An apparatus as claimed in one of the claims 1 to 4, characterized in that the reference period is based on the period of the highest possible waveforms.

6. An apparatus as claimed in one of the claims 1 to 5, characterized in that it satisfies the GSM and/or UMTS standard.

7. A data reconstruction method implemented in the apparatus as claimed in one of the claims 1 to 6, characterized in that it comprises the following steps:
storage of a certain number of data
determination of waveforms based on these stored data
determination of the period of these waveforms,
possible standardization during a same period called reference period of these waveforms,
reconstruction of waveforms established via correlation with already established waveforms, on the basis of the reference period,
reconstruction of the period of the reconstructed waveforms based on the period of the already established waveforms,
destandardization of the reconstructed waveforms, and
replacement of bad data by the reconstructed and destandardized waveforms.
